(19) United States
(12) Patent Application Publication
(10) Pub. No.: US 2009/0246897 A1
(43) Pub. Date: Oct. 1, 2009

(54) LED chip package structure and method for manufacturing the same

(76) Inventors: Bily Wang, Hsin Chu City (TW); Jonnie Chuang, Pan Chiao City (TW); Wen-Kuei Wu, Hukou Township (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/385,716

(22) Filed: Apr. 17, 2009

Related U.S. Application Data
(62) Division of application No. 11/483,619, filed on Jul. 11, 2006.

(51) Int. Cl. H01L 21/50

(52) U.S. Cl. 438/26; 257/E21.499

(57) ABSTRACT

An LED chip package structure includes a substrate unit, a light-emitting unit, and a colloid unit. The substrate unit has a substrate body, and a positive electrode trace and a negative electrode trace is respectively formed on the substrate body. The light-emitting unit has a plurality of LED chips arranged on the substrate body for generating light, wherein each of the LED chips has a positive side and a negative side respectively electrically connected with the positive electrode trace and the negative electrode trace. The colloid unit is covered over the substrate unit and the light-emitting unit for guiding the light from the light-emitting unit to form a series of light-generating areas on the colloid unit.

### RELATED APPLICATIONS

This application is a Divisional patent application of co-pending application Ser. No. 11/483,619, filed on 11 Jul. 2006. The entire disclosure of the prior application, Ser. No. 11/483,619, from which an oath or declaration is supplied, is considered a part of the disclosure of the accompanying Divisional application and is hereby incorporated by reference.

### BACKGROUND OF THE INVENTION

1. Field of The Invention

The present invention relates to an LED chip package structure and a method for manufacturing the-same, and particularly relates to a colloid unit covered over a substrate unit and a light-emitting unit for guiding the light from the light-emitting unit to form a series of light-generating areas on the colloid unit.

2. Description of the Related Art

Referring to FIGS. 1A-1C, a known LED package structure is manufactured via a wire-bounding process. The known LED package structure includes a substrate 1a, a plurality of LEDs 2a arranged on the substrate 1a, a plurality of wires 3a, and a plurality of fluorescent colloids 4a.

Each of the LEDs 2a is arranged on the substrate 1a, and each LED 2a has positive and negative electrode areas 21a, 22a respectively electrically connected with a corresponding positive area 11a and a corresponding negative electrode area 12a of the substrate 1a. Moreover, each fluorescent colloid 4a is correspondingly covered over each LED 2a and two wires 3a for protecting the LEDs 2a.

However, because each fluorescent colloid 4a needs to be covered over each corresponding LED 2a, the known package process is time-consuming. Moreover, because the fluorescent colloids 4a are separated from each other, a dark band is easily produced between the two fluorescent colloids 4a or the two LEDs 2a. Hence, the known LED package structure is hard to show a good vision for users.

### SUMMARY OF THE INVENTION

The present invention provides an LED chip package structure and a method for manufacturing the same. The LED chip package structure includes a plurality of LED chips arranged on a substrate body by an adhesive or a hot pressing method for generating light. The substrate unit is a PCB, a flexible substrate, an aluminum substrate, or a ceramic substrate. Each LED chip is electrically connected with the substrate unit via two corresponding wires by a wire-bounding method or via a plurality of solder balls by a flip-chip method. Moreover, a colloid unit is covered over the substrate unit and the light-emitting unit for guiding the light from the light-emitting unit to form a series of light-generating areas on the colloid unit. Hence, because the series of light-generating areas is continuous, no dark bands are produced between the LED chips. Furthermore, because the colloid unit is a continuous colloid body, the process of the LED chip package structure is simple for reducing manufacturing time.

In addition, each of the LED chips is a blue LED, and the colloid unit is a fluorescent colloid (an epoxy resin). Furthermore, the LED chip package structure can be applied to a back light module, a decorative lamp, a lighting lamp, or a scanner.

A first aspect of the present invention is an LED chip package structure that comprises: a substrate unit, a light-emitting unit, and a colloid unit. The substrate unit has a substrate body, and a positive electrode trace and a negative electrode trace are respectively formed on the substrate body. The light-emitting unit has a plurality of LED chips arranged on the substrate body for generating light, wherein each of the LED chips has a positive side and a negative side respectively electrically connected with the positive electrode trace and the negative electrode trace. The colloid unit is covered over the substrate unit and the light-emitting unit for guiding the light from the light-emitting unit to form a series of light-generating areas on the colloid unit.

A second aspect of the present invention is a method for packaging LED chips. The method comprises: providing a substrate unit, wherein the substrate unit has a substrate body, and a positive electrode trace and a negative electrode trace are respectively formed on the substrate body; arranging a light-emitting unit on the substrate body, wherein the light-emitting unit has a plurality of LED chips arranged on the substrate body for generating light, and each of the LED chips has a positive side and a negative side respectively electrically connected with the positive electrode trace and the negative electrode trace; and then covering a colloid unit over the substrate unit and the light-emitting unit for guiding the light from the light-emitting unit to form a series of light-generating areas on the colloid unit.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

The various objects and advantages of the present invention will be more readily understood from the following detailed description when read in conjunction with the appended drawings, in which:

FIG. 1A is a perspective view of an LED package structure according to the prior art;

FIG. 1B is a front view of an LED package structure according to the prior art;

FIG. 1C is a top view of an LED package structure according to the prior art;

FIG. 2A is a perspective view of an LED chip package structure according to the first embodiment of the present invention;

FIG. 2B is a top view of an LED chip package structure according to the first embodiment of the present invention;

FIG. 2C is a top view of a larger and parallel-type LED chip package structure according to the second embodiment of the present invention;

FIG. 2D is a top view of an reassembled LED chip package structure from the second embodiment of the present invention;

FIG. 3A is a perspective view of an LED chip package structure according to the third embodiment of the present invention;

FIG. 3B is a top view of an LED chip package structure according to the third embodiment of the present invention;

FIG. 3C is a top view of a larger and serial-type LED chip package structure according to the fourth embodiment of the present invention;

FIG. 3D is a top view of an reassembled LED chip package structure from the fourth embodiment of the present invention;

FIG. 4A is a perspective view of an LED chip package structure according to the fifth embodiment of the present invention;

FIG. 4B is a top view of an LED chip package structure according to the fifth embodiment of the present invention;

FIG. 4C is a top view of a larger and serial-type LED chip package structure according to the sixth embodiment of the present invention;

FIG. 4D is a top view of an reassembled LED chip package structure from the sixth embodiment of the present invention;

FIG. 5 is a flowchart of an LED chip package structure according to the first embodiment of the present invention;

FIG. 6 is a flowchart of an LED chip package structure according to the third embodiment of the present invention; and

FIG. 7 is a flowchart of an LED chip package structure according to the fifth embodiment of the present invention.

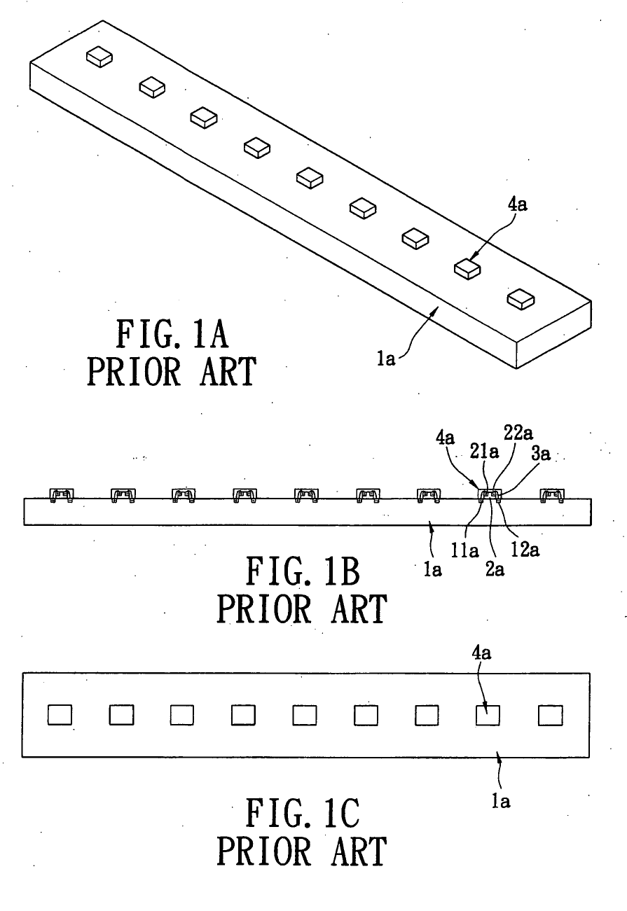

### DETAILED DESCRIPTION OF PREFERRED BEST MOLDS

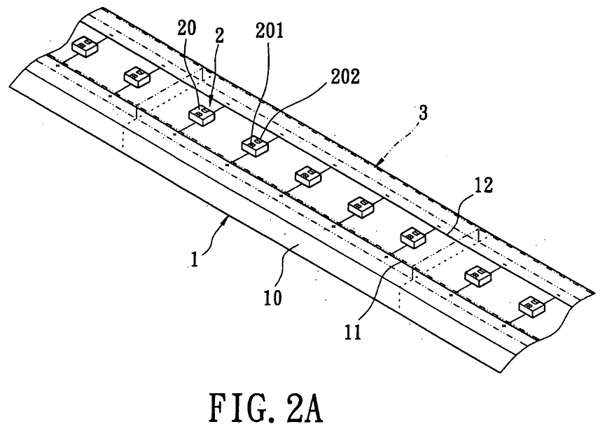

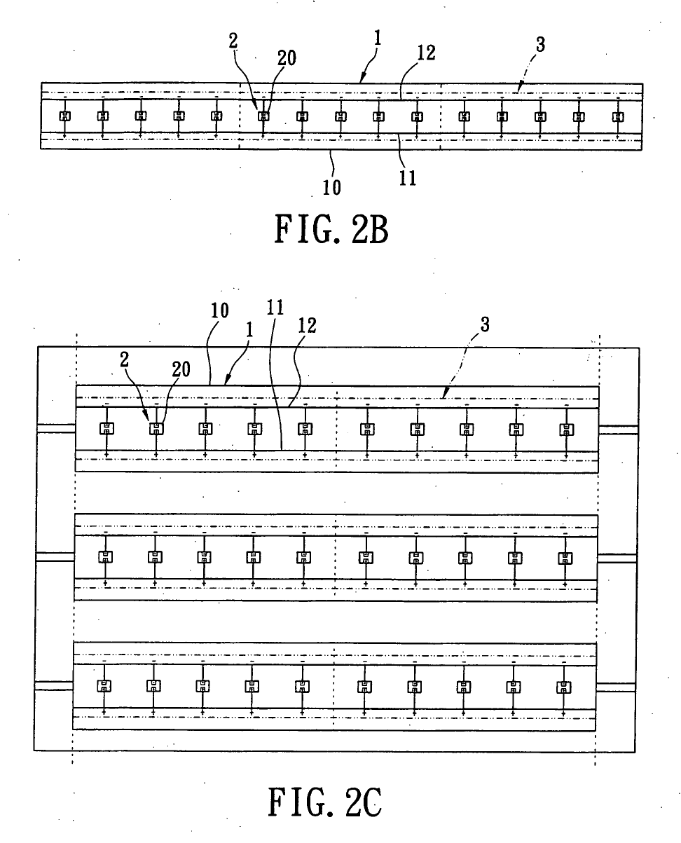

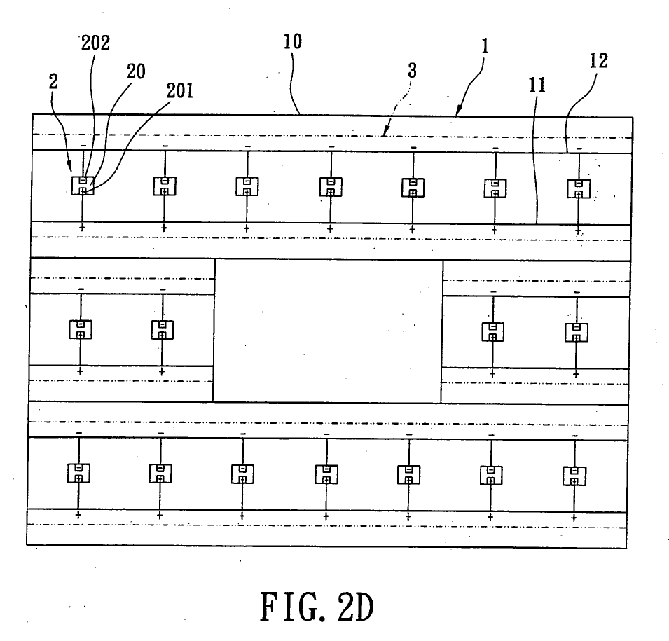

Referring to FIGS. 2A-2B, a first embodiment of the present invention provides an LED chip package structure, comprising a substrate unit 1, a light-emitting unit 2, and a colloid unit 3.

The substrate unit has a substrate body 10, and a positive electrode trace 11 and a negative electrode trace 12 respectively formed on the substrate body 10 by an etching, a printing or any other forming methods. The light-emitting unit 2 has a plurality of LED chips 20 arranged on the substrate body in a straight line by an adhesive or a hot pressing method for generating light. Moreover, each of the LED chips 20 has a positive side 201 and a negative side 202 parallel electrically connected with the positive electrode trace 11 and the negative electrode trace 12 via corresponding wires, respectively. Furthermore, the positive side 201 and the negative side 202 can also parallel electrically connected with the positive electrode trace 11 and the negative electrode trace 12 via corresponding solder balls (not shown), respectively. In addition, the solder balls are arranged on the substrate unit 1 by a hot-pressing method. Furthermore, the colloid unit 3 is covered over the substrate unit 1 and the light-emitting unit 2 for guiding the light from the light-emitting unit 2 to form a series of light-generating areas on the colloid unit 3. The colloid unit 3 can also prevent the light-emitting unit 2 from being damaged.

Referring to FIG. 2C, a second embodiment of the present invention provides a larger and parallel-type LED chip package structure that comprises a plurality of light-emitting units 2 respectively arranged on a corresponding substrate unit 1 in a plurality of straight lines via the parallel method of the first embodiment. Moreover, the larger LED chip package structure can be cut into a plurality of slender LED package structures, and the slender LED package structures can be arranged into any shape such as a hollow square as shown in FIG. 2D.

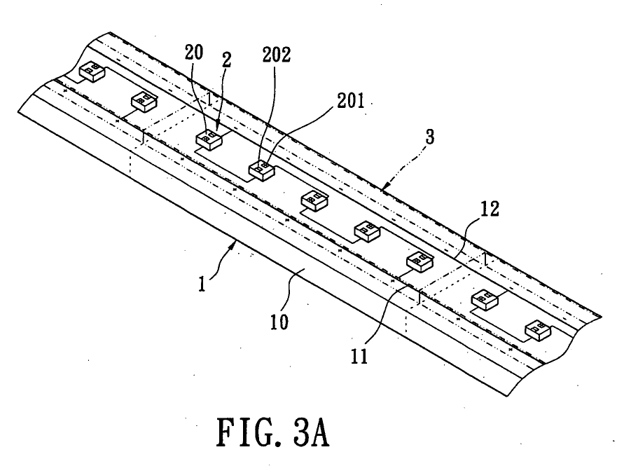

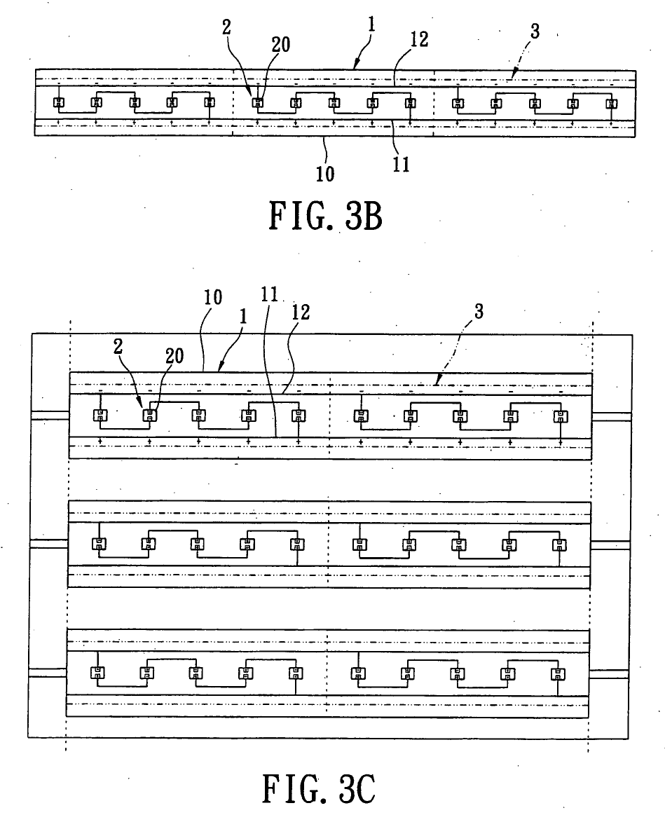

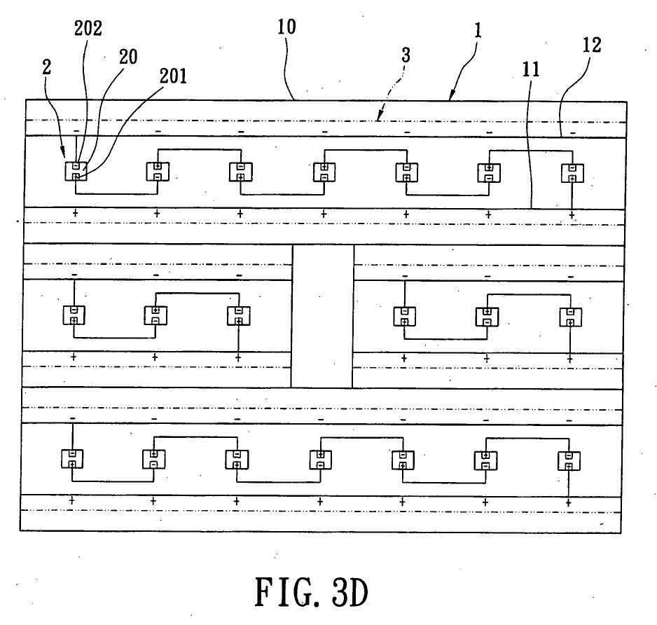

Referring to FIGS. 3A-3B, the difference between a third embodiment and the first embodiment is that in the third embodiment an arrangement direction of the positive electrode side 201 of each LED chip 20 is opposite to that of an adjacent LED chip. Moreover, the positive side 201 and the negative side 202 of each of the LED chips 20 are serially electrically connected with the positive electrode trace 11 and the negative electrode trace 12 via corresponding wires, respectively. The above serial shape appears to be U-shaped between every two LED chips 20.

Referring to FIG. 3C, a fourth embodiment of the present invention provides a larger and serial-type LED chip package structure that comprises a plurality of light-emitting units 2 respectively arranged on a corresponding substrate unit 1 via the serial method of the third embodiment. Moreover, the larger LED chip package structure can be cut into a plurality of slender LED package structures, and the slender LED package structures can be arranged into any shape such as a hollow square as shown in FIG. 3D.

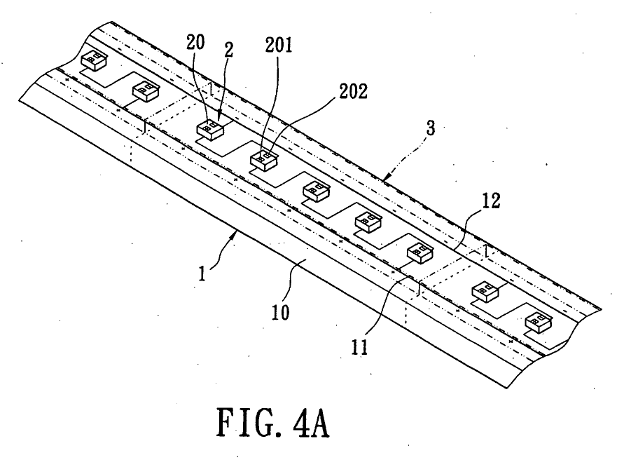

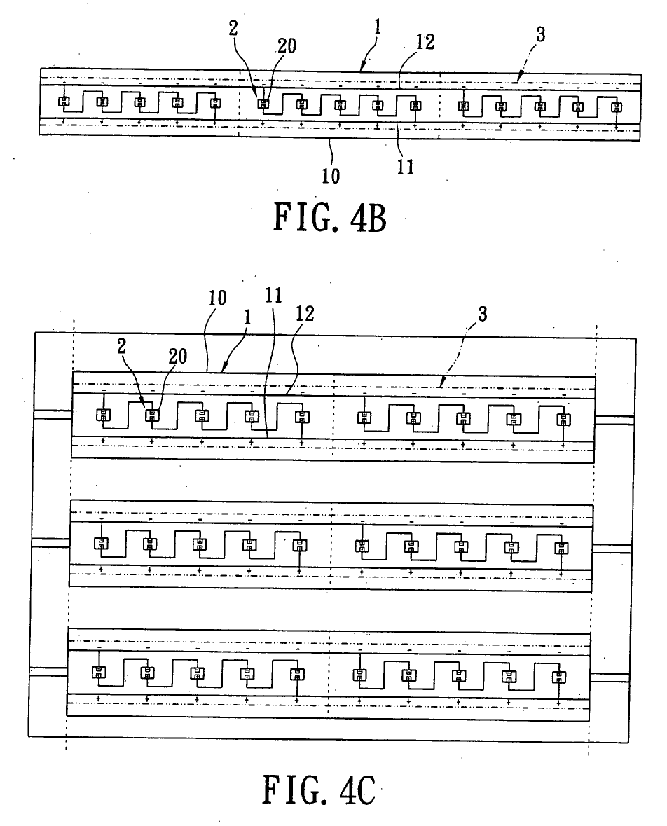

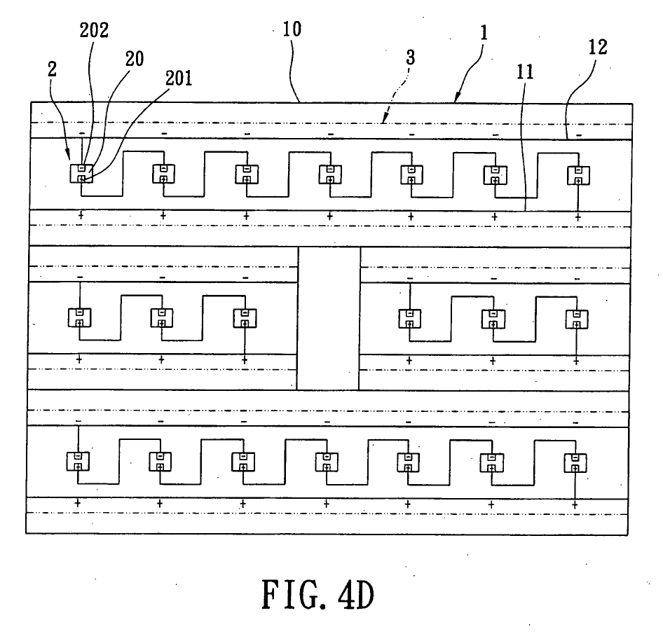

Referring to FIGS. 4A-4B, the difference between a fifth embodiment and the third embodiment is that in the fifth embodiment an arrangement direction of the positive electrode side 201 of each LED chip 20 is the same as that of an adjacent LED chip. Moreover, the positive side 201 and the negative side 202 of each of the LED chips 20 are serially electrically connected with the positive electrode trace 11 and the negative electrode trace 12 via corresponding wires, respectively. The above serial shape appears to be S-shaped between every two LED chips 20.

Referring to FIG. 4C, a sixth embodiment of the present invention provides a larger and serial-type LED chip package structure that comprises a plurality of light-emitting units 2 respectively arranged on a corresponding substrate unit 1 via the serial method of the third embodiment. Moreover, the larger LED chip package structure can be cut into a plurality of slender LED package structures, and the slender LED package structures can be arranged into any shape such as a hollow square as shown in FIG. 4D.

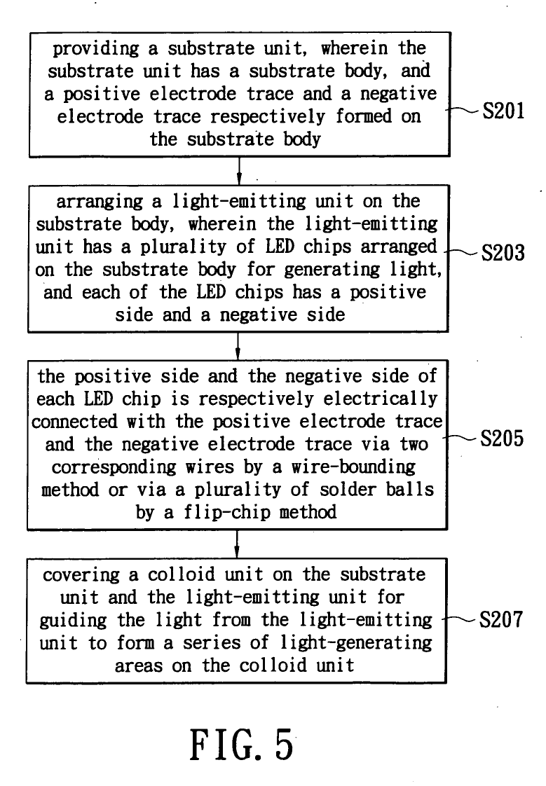

FIG. 5 shows a flowchart of an LED chip package structure according to the first embodiment of the present invention. The method comprises: providing a substrate unit 1, wherein the substrate unit 1 has a substrate body 10, and a positive electrode trace 11 and a negative electrode trace 12 respectively formed on the substrate body 10 (S201); and then arranging a light-emitting unit 2 on the substrate body 10, wherein the light-emitting unit 2 has a plurality of LED chips 20 arranged on the substrate body 10 for generating light, and each of the LED chips 20 has a positive side 201 and a negative side 202 (S203). Moreover, the positive side 201 and the negative side 202 of each LED chip 20 is respectively electrically connected with the positive electrode trace 11 and the negative electrode trace 12 via two corresponding wires by a wire-bounding method or via a plurality of solder balls by a flip-chip method (S205). In addition, the method further comprises covering a colloid unit 3 on the substrate unit 1 and the light-emitting unit 2 for guiding the light from the light-emitting unit 2 to form a series of light-generating areas on the colloid unit 3 (S267).

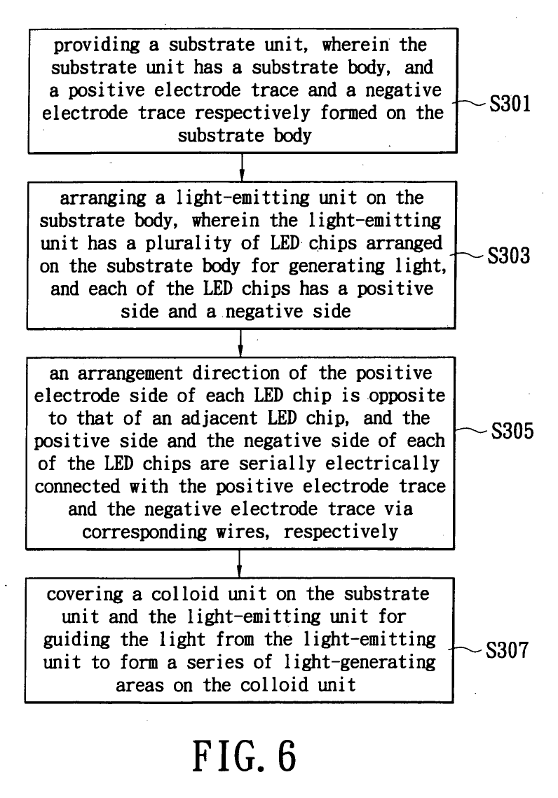

FIG. 6 shows a flowchart of an LED chip package structure according to the third embodiment of the present invention. The difference between the third embodiment and the first embodiment is that in the step of S305 an arrangement direction of the positive electrode side 201 of each LED chip 20 is opposite to that of an adjacent LED chip. Moreover, the positive side 201 and the negative side 202 of each of the LED chips 20 are serially electrically connected with the positive electrode trace 11 and the negative electrode trace 12 via corresponding wires, respectively.

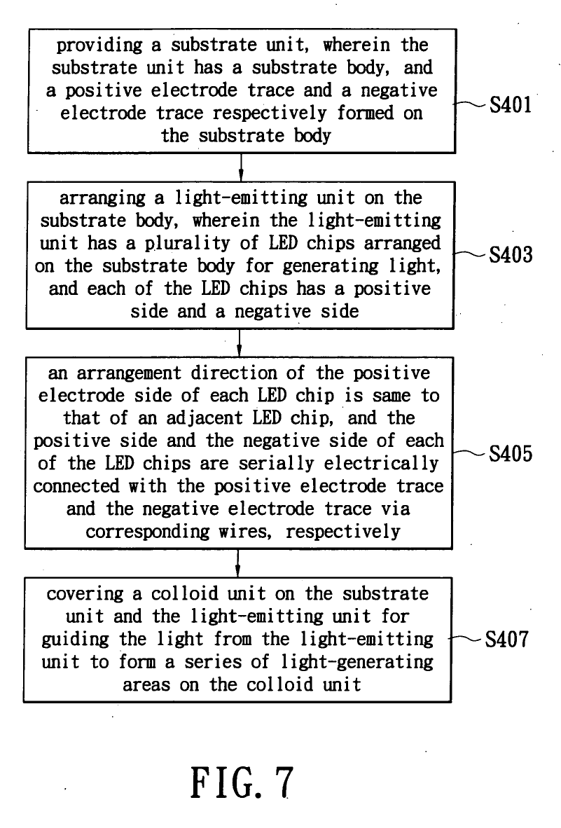

FIG. 7 shows a flowchart of an LED chip package structure according to the fifth embodiment of the present invention. The difference between the fifth embodiment and the third embodiment is that in the step of S405 an arrangement direction of the positive electrode side 201 of each LED chip 20 is same to that of an adjacent LED chip. Moreover, the positive side 201 and the negative side 202 of each of the LED chips 20 are serially electrically connected with the positive electrode trace 11 and the negative electrode trace 12 via corresponding wires, respectively.

In conclusion, the LED chips 20 are arranged on the substrate body 10 by the adhesive or the hot pressing method for generating light. Moreover, the colloid unit 3 is covered over the substrate unit 1 and the light-emitting unit 2 for guiding the light from the light-emitting unit to form the series of light-generating areas on the colloid unit 3. Hence, because the series of light-generating areas is continuous, no dark bands are produced between every two LED chips 20. Furthermore, because the colloid unit 3 is a continuous colloid body, the process of the LED chip package structure is simple for reducing manufacturing time.

Although the present invention has been described with reference to the preferred best molds thereof, it will be understood that the invention is not limited to the details thereof. Various substitutions and modifications have been suggested. in the foregoing description, and others will occur to those of ordinary skill in the art. Therefore, all such substitutions and modifications are intended to be embraced within the scope of the invention as defined in the appended claims.

What is claimed is:

1. A method for packaging LED chips, comprising:
providing a substrate unit, wherein the substrate unit has a substrate body, and a positive electrode trace and a negative electrode trace respectively formed on the substrate body;
arranging a light-emitting unit on the substrate body, wherein the light-emitting unit has a plurality of LED chips arranged on the substrate body for generating light, and each of the LED chips has a positive side and a negative side respectively electrically connected with the positive electrode trace and the negative electrode trace; and
covering a colloid unit on the substrate unit and the light-emitting unit for guiding the light from the light-emitting unit to form a series of light-generating areas on the colloid unit.

2. The method as claimed in claim 1, wherein the substrate unit is a PCB, a flexible substrate, an aluminum substrate, or a ceramic substrate.

3. The method as claimed in claim 1, wherein the positive side and the negative side of each LED chip are respectively electrically connected with the positive electrode trace and the negative electrode trace via two corresponding wires by a wire-bounding method.

4. The method as claimed in claim 1, wherein the positive side and the negative side of each LED chip are respectively electrically connected with the positive electrode trace and the negative electrode trace via a plurality of solder balls by a flip-chip method.

5. The method as claimed in claim 4, wherein the solder balls are arranged on the substrate unit by a hot-pressing method.

6. The method as claimed in claim 1, wherein the positive side and the negative side of each LED chip are respectively electrically connected with the positive electrode trace and the negative electrode trace by a parallel method.

7. The method as claimed in claim 1, wherein the positive side and the negative side of each LED chip are respectively electrically connected with the positive electrode trace and the negative electrode trace by a serial method.

8. The method as claimed in claim 1, wherein the LED chips are arranged on the substrate body in a straight line to form an LED chip package structure.

9. The method as claimed in claim 8, wherein the LED chip package structure is cut into a plurality of slender LED package structures, and the slender LED package structures are arranged into a predetermined shape.

10. The method as claimed in claim 1, wherein the LED chips are arranged on the substrate body in a plurality of straight lines to form an LED chip package structure.

11. The method as claimed in claim 10, wherein the LED chip package structure is cut into a plurality of slender LED package structures, and the slender LED package structures are arranged into a predetermined shape.

12. The method as claimed in claim 1, wherein each of the LED chips is a blue LED, and the colloid unit is a fluorescent colloid.

13. The method as claimed in claim 1, wherein the fluorescent colloid is an epoxy resin.
